(19) United States
(12) Patent Application Publication
(10) Pub. No.: US 2012/0279856 A1
(43) Pub. Date: Nov. 8, 2012

(54) Tin Oxide Ceramic Sputtering Target and Method of Producing It

(76) Inventors: Eugène Medvedovski, Providence, RI (US); Olga Yankov, Coventry, RI (US); Christopher J. Szepesi, West Warwick, RI (US)

(21) Appl. No.: 13/500,381

(22) PCT Filed: Sep. 21, 2010
(86) PCT No.: PCT/EP2010/005757

§ 371 Date: Jul. 20, 2012

Related U.S. Application Data
(60) Provisional application No. 61/251,815, filed on Oct. 15, 2009.

(30) Foreign Application Priority Data
Dec. 7, 2009 (EP) 09015118.4
Jun. 16, 2010 (EP) 10006212.4

(51) Int. Cl. C23C 14/08; C04B 35/457; C23C 14/34

(52) U.S. Cl. 204/298.13; 264/678; 264/676

(57) ABSTRACT

The invention describes a sputtering target comprising a ceramic body having tin oxide as a major constituent and between 0.5 and 15 wt % of at least two other oxides, one of which being antimony oxide, the target having a density of at least 90%, and preferably at least 95%, of the theoretical density (TD) and an electrical resistivity of less than 50 Ohm·cm, and the target having a planar or rotary configuration with a sputtering area of at least 10 cm², and preferably at least 20 cm². Also described is a process for manufacturing this sputtering target according comprising the steps of: —providing for a slurry comprising tin oxide and said at least two other oxides, —shaping of a green body from said slurry, and drying said green body, —firing of said green body at a temperature between 1050 and 1250° C., thereby obtaining a pre-shaped target, and —grinding of said pre-shaped target to its final dimensions.

### TECHNICAL FIELD AND BACKGROUND

This invention is related to the ceramic composition of tin oxide-based ceramic sputtering targets and a method of producing sintered bodies containing tin oxide. Ceramic sputtering targets are used for producing of transparent conductive oxide (TCO) thin films for optoelectronic applications, such as LCD, touch panels, electrochromic devices and others, as well as for thin films for photovoltaic applications. Also the sintered electrically conductive tin oxide-based ceramics (or films based on these ceramics) may be used for preparation of thermoelectric devices, electrodes, heating elements and some other products, where high density and low electrical resistivity (or high electrical conductivity) are required.

The formation and application of TCO thin films based on semiconducting tin oxide ceramics may have a sufficient benefit due to the manufacturing cost of currently used indium oxide-based ceramic sputtering targets where, in some cases, the application conditions do not afford the use of expensive indium-based ceramics. Considering tin oxide thin films (and tin oxide ceramics), pure tin oxide is not a highly conductive material, and therefore dopants promoting electrical conductivity are required. As one of the most effective dopants, antimony oxide is used for tin oxide, since it significantly increases the electrical conductivity of the ceramics and films.

Usually, transparent conductive thin film coatings for optoelectronic and energy conversion applications are produced employing sputtering technology, e.g. by pulse laser deposition, radio frequency sputtering, and direct current (DC) sputtering, where sputtering targets are the source of TCO films. In particular, a DC magnetron sputtering technique is the most reproducible and economical viable process. In order to enable a DC magnetron sputtering process to be applicable, sputtering targets can have rather low electrical resistivity, in the tens of Ohm·cm, and in some cases less than 50-80 Ohm·cm. Industrial sputtering equipment and processes use rather large size sputtering targets with planar and rotary configurations, which can consist of discs, tiles or other shapes, with for example areas larger than 10-20 cm², and hollow cylinders with for example diameters greater than 10 cm; and a thickness of the ceramic body of the target of at least 4 mm.

Transparent conductive SnO₂—Sb₂O₃ thin films may be obtained through sputtering either by a reactive sputtering process using Sn:Sb metallic compositions or using SnO₂:Sb₂O₃ ceramic sputtering targets. It is known since long that the reactive sputtering process is not very stable and it does not allow to obtain high quality reproducible TCO films. Therefore, the use of ceramic oxide targets is more preferable for the industrial applications. The earlier published sputtering test results with ceramic targets in laboratory conditions were obtained using RF magnetron sputtering processes since the targets did not have high density and high electrical conductivity. In order to realize a DC magnetron sputtering process and obtain high quality TCO films, ceramic sputtering targets can have a high density and a low electrical resistivity, as well as some other properties (e.g. rather high thermal conductivity), making them suitable for sputtering, and minimizing cracking of the targets during film processing. In particular, the density of the sputtering targets can be for example 90% of the theoretical density (TD) or greater, for example, 95% of TD or greater. High density of sputtering targets provides low arcing during sputtering, thin film uniformity and thickness, and guarantees a long operational sputtering cycle. Besides, denser ceramics usually have higher electrical conductivity. However, in general, the density of SnO₂ and SnO₂—Sb₂O₃ ceramics is not very high—only about 60% of TD or below—and this fact is explained by evaporation-condensation during the sintering process, i.e. the partial decomposition of SnO₂ and volatilization of SnO at temperatures greater than 1200-1250° C.

Hot pressing or hot isostatic pressing or spark plasma sintering processes may promote, in general, ceramic densification. However, regarding tin oxide-based ceramics, these methods do not provide high densification due to the volatilization of tin oxide. Even when the starting powders are mixed thoroughly, non uniform densification may take place. Also these methods are expensive, they require sufficient maintenance, and they have a serious limitation in terms of the obtainable size of the targets.

It is desirable to have a ceramic composition based on SnO₂—Sb₂O₃ and using the technology that will provide high density of the sintered bodies. Since their low electrical resistivity makes them suitable for DC magnetron sputtering, that will provide film properties, e.g. film resistivity and transmittance that are acceptable for TCO thin film applications. One of the possible routes to obtain high density and acceptable electrical properties is to use an addition of sintering aids, which, due to a formation of a liquid phase during firing, promote the particle attraction of the compacted ceramic bodies during sintering and fill the pores in these bodies. Different oxides were tested as the additives to increase density of SnO₂ and SnO₂—Sb₂O₃ ceramic bodies, and, particularly, sputtering targets.

For example, in U.S. Pat. No. 5,026,672, the addition of ZnO, SiO₂ and Al₂O₃ in certain amounts was said to improve sinterability of SnO₂ and SnO₂—Sb₂O₃ ceramic sputtering targets, the latter containing however 30 wt % of Sb₂O₃. These ceramics only had a density greater than 90% of TD at firing temperatures of about 1500° C. in air atmosphere. At this temperature, SnO₂'s partial decomposition and volatilization usually take place, and therefore, the ceramic uniformity is not very high, i.e. the surface of the ceramics has a lack of SnO₂ in comparison with the bulk or middle. In this case, it may be observed that the surface of the ceramics is softer than the middle. As a consequence, the sputtering process and film formation will not be very stable and consistent.

Ceramic compositions based on tin oxide with additives of CuO, ZnO, Sb₂O₃ are also proposed in US 2006/0016223 A1, for manufacturing of the electrodes in glass melting electrical furnaces. However, a rather high density of the sintered bodies was achieved only at firing temperatures of at least 1400° C. using air atmosphere, and hence the ceramic uniformity is not very high due to SnO₂ partial decomposition and volatilization (i.e. the surface of the ceramics has a lack of SnO₂ in comparison with the middle), making the proposed electrodes (besides having unadapted geometries) not suitable for TCO thin film sputtering purposes.

Low-temperature densification of SnO₂ with a Sb₂O₃ dopant was attained when the composition contained vitreous glass frits in sufficient amounts, as is disclosed in US 2006-0162381 A1. The used glass frits contained a combination of the oxides SiO₂+B₂O₃+BaO+Al₂O₃. However, such compositions will not be suitable for sputtering targets applications due to a lack of conductivity and the presence of a high quantity of an insulating glassy phase. Regarding TCO film production, it would lead to lower transmittance and conductivity of the obtained films.

One composition providing good sinterability of the ceramics was based on the system of SnO₂—Sb₂O₃—CuO, as disclosed by D. Nisiro et al. in J. Mater. Sci., 38, 2003, 2727-2742. However, the authors, using the described technology, made only small bars (a few mm in a cross-section and about 40-50 mm in length) from this ceramics. Also, this ceramic and technology were not designed for sputtering targets manufacturing, since that has higher requirements. Full density was said to be obtained at 1200° C., but the microstructure of these ceramics was not homogeneous with a presence of small (a few microns) and, especially, larger grains of SnO₂ (15-30 μm up to 40-50 μm). Also, there is a presence of secondary grain boundary phases and some degree of intergranular porosity, causing the appearance of clusters. The secondary phases might be crystalline phases based on compounds of copper stannates (SnO₂—CuO), antimony stannates (SnO₂—Sb₂O₃), copper antimonates (Sb₂O₃—CuO) and some others. They can be detected using XRD and microscopy analyses. Such non homogeneous structures of ceramics, as known from practical experience, is not suitable for obtaining reproducible high-quality thin transparent films without defects.

In WO2009/060901 a SnO₂-based sputtering target is formed from a sintered compact comprising more than 10 ppm and less than 1 wt % of Sb₂O₃, and no more than a total of 20 wt % of Ta₂O₅ and/or Nb₂O₅, with the remainder being made up of SnO₂ and unavoidable impurities.

Regarding the ceramic compositions for TCO sputtering target applications, and particularly, SnO₂—Sb₂O₃-based compositions, these ceramics need to be of a high purity to minimize light absorption negatively affecting film transparency. As this is related to the presence of transition metal oxides in the ceramic composition, there are restrictions in the ceramic compositions for sputtering targets.

Because of industrial needs, tin oxide-based ceramic sputtering targets can have the composition and technology which provide high density of the ceramics, low electrical resistivity and other properties, making them suitable for industrial DC magnetron sputtering processes. The targets can have rather large sizes, e.g. rectangular, square or round shapes with areas of for example 100-300 cm² or greater, and a thickness of for example at least 4 mm of the ground (machined) bodies (i.e. the thickness of the ceramic bodies before grinding can be at least 5.5-6 mm) with a good flatness for bonding to metallic backing. Rotary targets consisting of hollow cylindrical ceramic bodies bonded with a metallic backing tube also are required by the industry. Currently, there are no sputtering targets of SnO₂- or SnO₂—Sb₂O₃-based compositions with large dimensions that have a high density (for example higher than 90% of TD, or possibly higher than 95% of TD), low electrical resistivity (for example below than 50 Ohm·cm), making them suitable for DC sputtering process. Also, a rather high thermal conductivity is useful, providing thermal stress reduction during sputtering, thus yielding thin films with low electrical resistivity and high transmittance. In order to improve the film uniformity and film properties, the ceramic sputtering targets can have a uniform microstructure in terms of grain size and a minimal content (or even absence) of secondary phases (the above mentioned crystalline stannates and others) uniformly distributed amongst the major phase.

The invention aims to provide for ceramic target compositions needed by industry, as described in this paragraph.

### SUMMARY

Viewed from a first aspect, the invention can provide a sputtering target comprising a ceramic body having tin oxide as a major constituent and between 0.5 and 15 wt % of at least two other oxides, one of which being antimony oxide, the at least one other oxide being selected from the group consisting of CuO, CoO, Bi₂O₃, ZnO, Al₂O₃, TiO₂, MnO₂, In₂O₃, Ga₂O₃, GeO₂, SiO₂ and P₂O₅, or the at least one other oxide being both ZnO and Nb₂O₅, said target having a density of at least 90%, and in some embodiments at least 95%, of the theoretical density (TD) and an electrical resistivity of less than 50 Ohm·cm, and said target has a planar or rotary configuration with a sputtering area of at least 10 cm², and in some embodiments at least 20 cm². In one embodiment discs or tiles are provided having a sputtering area of at least 100 cm². Rotary configurations could consist of a hollow cylinder having a diameter of at least 10 cm. The example configurations described before can have a ceramic body of the target having a thickness of at least 4 mm. In one embodiment the sputtering target has a thermal conductivity in the range of 10-20 W/m-K at 300° C. In another embodiment the electrical resistivity of the bulk of the ceramic body (its specific volume electrical resistivity) is less than 10 Ohm·cm (measured at room temperature). Values for the electrical resistivity of less than 1 Ohm·cm, even less than 0.2 or less than 0.1 Ohm·cm can also be obtained.

In another embodiment, the target has a uniform microstructure consisting of particles, of which between 60 to 90% having a grain size between 5 and 25 μm, and between 65 to 75% having a grain size between 7 and 15 μm; and with the presence of less than 10% of a secondary phase, as described above.

In one embodiment this target can comprise, besides tin oxide, between 0.5 and 15 wt % of at least three other oxides, one of which being antimony oxide, the two other oxides being either one of the following groups:
CuO and CoO,
CuO, ZnO and Al₂O₃,
CuO, ZnO and Nb₂O₅,
CuO and Ga₂O₃,
CuO and Bi₂O₃.

In another embodiment the sputtering target can comprise, besides tin oxide and antimony oxide, between 1.5 and 5 wt % of the groups of the at least two other oxides described above.

Such a composition can consist of between 95.5 and 97 wt % of tin oxide, between 1 and 2.5 wt % of antimony oxide, and between 0.5 and 2 wt % of CuO, the sum of tin oxide, antimony oxide and CuO being 100%. As an alternative to this composition, further embodiments can consist of (besides tin oxide, antimony oxide and CuO):
between 0.05 and 1 wt % of CoO, the sum of tin oxide, antimony oxide, CuO and CoO being 100%, or
between 0.1 and 1 wt % of ZnO and between 0.001 and 0.003 wt % of Al₂O₃, the sum of tin oxide, antimony oxide, CuO, ZnO and Al₂O₃ being 100%, or
between 0.1 and 1 wt % of ZnO and between 0.05 and 0.5 wt % of Nb₂O₅, the sum of tin oxide, antimony oxide, CuO, ZnO and Nb₂O₅ being 100%, or
between 0.05 and 1 wt % of Bi₂O₃, the sum of tin oxide, antimony oxide, CuO and Bi₂O₃ being 100%, or
between 0.05 and 1 wt % of Ga₂O₃, the sum of tin oxide, antimony oxide, CuO and Ga₂O₃ being 100%.

Viewed from a second aspect, the invention can provide the use of a sputtering target as described above for manufacturing transparent conductive coatings.

Viewed from a third aspect, the invention can provide a process for manufacturing a sputtering target as described above, comprising the steps of:
providing for a slurry comprising tin oxide and said at least two other oxides,
shaping of a green body from said slurry,
heating of said green body, and firing at a temperature between 1050 and 1250° C., thereby obtaining a pre-shaped target, and
grinding of said pre-shaped target to its final dimensions.

In one embodiment, the green body is dried before firing it.

In another embodiment, the step of providing for a slurry may comprise the steps of:
providing for quantities of tin oxide and said at least two other oxides, the ratio of a said quantities corresponding to the composition of the ceramic sputtering target,
providing for an intermediate slurry comprising at least part of said tin oxide and at least part of said at least two other oxides,
drying said intermediate slurry to obtain a dry cake,
crushing said cake to obtain an intermediate powder,
firing said intermediate powder at a temperature between 700 and 950° C.,
de-agglomerating said fired intermediate powder,
mixing said de-agglomerated powder with the remainder of said quantities of tin oxide and said at least two other oxides, and using said mixture to form a slurry.

Where the target comprises CuO as described above, the intermediate slurry may consist of part of said quantity of said tin oxide, and all of the quantity of CuO.

In yet another embodiment, the tin oxide and the at least two other oxides in the slurry have an average particle size of less than 0.5 μm, and in one embodiment less than 0.4 μm. It is possible to provide for raw materials having this particle size before making the slurry, or obtaining the desired particle size during slurry formation, as is described below. In another embodiment the tin oxide and the at least two other oxides in said slurry have a specific surface area of at least 5.5 m²/g.

In an example process, the manufacturing of tin oxide-based ceramics with two or more dopants includes the colloidal preparation of the starting ceramic ingredients in a slurry that may be prepared either by direct mixing/milling of all required ingredients or by mixing/milling of all CuO with all or partial amounts of SnO₂, drying of the prepared slurry, transferring it to a powder, firing of the powder in the range of 700-950° C., de-agglomeration of it, and final slurry preparation from the obtained SnO₂—CuO compound and all residual ingredients, where the prepared slurry has average particle size of 0.4 μm or less and specific surface area of 5.5 m²/g or greater. Shaping of the target is done using available forming methods, such as casting, pressing (uniaxial or isostatic), extrusion, injection molding and others, depending on the required shape of the target. Firing of these shapes with temperatures in the range of 1050-1250° C. results in a final density of the ceramic target components of at least 95% of TD, while the ceramic components have planar and rotary configurations with areas larger than 10 cm² and a thickness of the ceramic body of at least 4 mm.

In one embodiment the firing of the green body is performed in a furnace at a temperature between 1050 and 1250° C. during a firing—also called soaking—period of 2 to 7 hrs. In another embodiment in said furnace, during heating up to the firing temperature, and during a first part of said soaking period, there is a flow of oxygen, and during a second part of said soaking period, there is a flow of reducing gas, for example consisting of nitrogen. In yet another embodiment said flow of both said oxygen and said reducing gas is between 0.25 and 2.5 l/min per kg of green body.

### DETAILED DESCRIPTION

Example tin oxide-based ceramics for sputtering targets have two or more dopants, one of them is antimony oxide, which accounts for an increase in electrical conductivity, and other constituents that promote the sinterability and do not significantly reduce, or even increase the electrical conductivity (or decrease electrical resistivity). The content of tin oxide SnO₂, as a major component, is for example more than 85%. The dopants, besides Sb₂O₃, may include one or more oxides, such as CuO, CoO, ZnO, Al₂O₃, Nb₂O₅, TiO₂, MnO₂, In₂O₃, Ga₂O₃, GeO₂, SiO₂, P₂O₅, Bi₂O₃, ZrO₂, Y₂O₃, Sc₂O₃, NiO and some others. The total content of the dopants is for example 0.5-15 wt % in order to provide for a high densification (obtaining more than 90% of the TD), low electrical resistivity and high thermal conductivity. Moreover, the total content of the dopants—besides antimony oxide—is in one embodiment between 1.5 and 5 wt % in order to improve the density further, for example to values higher than 95% of TD, and with electrical and thermal properties that are suitable for DC sputtering processes. The content of Sb₂O₃ is in one embodiment 1-2.5 wt % in order to achieve acceptable electrical properties (i.e. the electrical conductivity). One of the example dopants, besides Sb₂O₃, is copper oxide (CuO); however, other example dopants, such as CoO, ZnO, Nb₂O₅, TiO₂, Al₂O₃, Bi₂O₃ may be used jointly with CuO. These example oxide combinations provide for low firing temperatures of the ceramics (below 1250° C.), thus preventing or minimizing the evaporation of SnO₂ during firing and thus ensuring high ceramic sinterability and densification and stable properties.

An example preparation of the ceramics includes the wet colloidal processing using different equipments, such as ball mill, attritor, or other units contained mixing/milling media (e.g. ceramic or polymeric), where starting ingredients, such as SnO₂, Sb₂O₃ and other dopants, as well as water and dispersing agents are mixed and milled. All solid ingredients (powders) may be added to the liquid media and milled together, or some of the solid ingredients (powders) may be added first, milled certain time, and then other ingredients are added.

An example of the prepared slurry (also called slip or suspension) has an average particle size of 0.5 μm or less and a specific surface area of at least

4.5 m²/g, and, in one embodiment, an average particle size of 0.4 μm or less with a specific surface area of at least 5.5 m²/g. It is achieved by the use of raw oxide materials having similar values of avg. particle size and specific surface area, and by the intensive milling process that guarantees a high level of homogenization of the ingredients in the slurry. The above mentioned properties of the solids in the slurry, in particular the particle size distribution and specific surface area, as well as a high level of dispersion and homogeneity of ingredients in the slurry can provide for a high level of ceramic densification and uniformity of microstructure, thus minimizing the formation of secondary phases and, thereafter, achieving a low electrical resistivity of the ceramics. If the slip has coarser particles, for example an average particle size higher than 0.4 μm and/or a specific surface area lower than 4.5 m²/g, the sinterability of the ceramics can be not high enough due to a lack of particle compaction.

The mixing/milling of the ingredients may be conducted using the addition of all required ingredients into the mixing/milling equipment with a liquid phase (water with dispersing agents).

The properties of the prepared slurry are measured, and then it is used for the shaping of the ceramic bodies. In one embodiment the mixing/milling of ingredients may be conducted by preparation of an intermediate slurry containing all of the CuO (and some other dopants) with all or only part of the required SnO₂ quantities, drying of the prepared suspension, crushing of the dried cake to obtain a powder or using a spray drying process or other techniques, firing this powder in a furnace at a temperature between 700 and 950° C., deagglomeration of the fired powder and then using it for the final slurry preparation; in this case, other ingredients are added jointly with this prepared SnO₂—CuO-based compound (the so-called “grog”) into the mixing/milling equipment for the final slurry processing. The properties of the finally prepared slurry are again measured, and then it is used for the shaping of the green bodies.

Shaping of the green body of the tin oxide-based ceramic sputtering target can be conducted using all available methods depending on the required shape, available equipment and in accordance with required quantities. Slip casting into plaster or polymer molds, pressing (uniaxial or isostatic), pressure filtration, extrusion, tape casting, injection molding and other methods may be utilized. Depending on the shaping method, special binder systems may be utilized. The ceramic target components may be of planar or rotary configurations, e.g. discs, tiles or other shapes, such as ovals, and hollow cylinders.

The green body of the tin oxide-based sputtering target is for example fired in a furnace in the temperature range of 1050-1250° C., and in some embodiments using special gas flow firing conditions. If the firing temperature is below 1050° C. sintering is not completed, and the obtained density is low. When the firing temperature is greater than 1250° C. tin oxide starts evaporating through its partial decomposition. This leads to sputtering targets having a rough surface, whereas the targets provided by the invention are nice and shiny, and have a smooth surface. Also, when the firing temperature is greater than 1250° C., excessive amounts of “secondary” phases, such as copper stannates and antimony stannates may occur, resulting in an increase of the ceramics electrical resistivity. The soaking time used for the firing is for example between 2 and 7 hrs. A shorter soaking time can lead to low densification, and soaking times longer than 7 hrs promote an increase in electrical resistivity and extra grain growth. Firing is for example conducted under an oxygen flow; the level of oxygen is set between 0.25 and 2.5 l/min/kg of sinterable product. The use of oxygen flow reduces the partial decomposition of tin oxide, especially at temperatures around 1150 to 1250° C. If the oxygen level is below 0.25 l/min/kg of product, the density can be lowered, but the use of too high oxygen levels (e.g. greater than 2.5 l/min/kg of product) does not promote further densification; and the electrical resistivity of the ceramics also remains at the same level or is even slightly higher.

Upon introduction of reducing gaseous conditions during firing, particularly in the second part of the soak and during cooling, a significant reduction of electrical resistivity of the ceramics is promoted due to the occurrence of crystalline lattice defects promoting electrical conductivity. If a reducing gas, and particularly nitrogen, is introduced in the beginning of the soak, the achieved density is not high enough, but if this gas is introduced after the soak, the electrical resistivity is rather high due to a lack of crystalline lattice defects. The content of nitrogen can be in the range of 0.25-2.5 l/min/kg of product. If this flow is less than 0.25 l/min/kg of product, the obtained resistivity is still high, but when the nitrogen flow increases beyond 2.5 l/min/kg of product the electrical resistivity does not decrease any more. The introduction of nitrogen gas does not affect the density of the ceramics if its flow is in the preferred range.

When the desired density is achieved, the fired tin oxide-based ceramic sputtering targets are ground to create low roughness and an appropriate quality of the surface for bonding with a backing material and for sputtering. The ceramic target components may be, as mentioned above, with planar or rotary configurations; the areas of the target components can be larger than 10 cm², e.g. discs with diameters of 100-200 mm or larger, tiles with sides of 100-200 mm or larger (or other shapes such as ovals), hollow cylinders with diameters of 100-150 mm or larger, with a thickness of 4-10 mm or greater.

The proposed compositions and technological features allow the formation of tin oxide-based ceramic sputtering targets having for example densities of at least 90% of TD, and even greater than 95% of TD. The ceramics can have low electrical resistivity with values even down to below 10 Ohm·cm (at room temperature) making them extremely suitable for DC magnetron sputtering. They also can have a thermal conductivity in the range of 10-20 W/m-K (measured at 300° C.) that is very acceptable for sputtering processes, since a good release of the heat from the material in the chamber is possible, thus minimizing thermal stress of the ceramic targets. Also, the proposed compositions and technology can result in a uniform microstructure, i.e. this microstructure consists of small cassiterite (tin oxide) grains having a size mostly between 5 and 25 μm (for at least 60 up to 90%), with a majority (about 65-75%) of the grains having a size of 7-15 μm, without the presence of large and elongated grains of 40-50 μm or even greater. It is recognized that the grain size and the contents of the grains with particular grain sizes may be determined only approximately, but microscopic studies allow to evaluate a general uniformity of the microstructure. For the example targets, the presence of secondary crystalline phases, such as copper and antimony stannates (amongst others) is not detected by XRD or microscopic analysis, or their occasional presence may be insignificant (below 5-10%).

The ground sputtering targets, which are bonded to the backing material (plate or tube), are sputtered under known and established conditions for the thin film preparation. These conditions depend on the sputtering equipment design, target design and some other features. The TCO film quality (morphology, film resistivity and transparency) obtained by using the targets according to the invention, are acceptable in accordance with industrial requirements. Although ceramic sputtering targets have to have minimal amounts of transition metal oxides for a high level of film transparency, surprisingly, the proposed ceramics containing small amounts of transition metal oxides yield highly transparent thin films, due to a high ceramic uniformity and high density and a small amount of a glassy phase uniformly distributed among the cassiterite crystalline phase. The TCO film properties depend on sputtering and film treatment conditions (e.g. sputtering powder, gas pressure, oxygen/argon level, temperature of the substrate, annealing, etc.), and, by optimizing these conditions, a high level of the films properties is attained. Sputtering process and conditions may not be particularly limited, however, in particular, film transparency is up to 85-90% or even greater for the films with thicknesses of 100-150 nm in the visible range, and this is quite good for optoelectronic and solar cell applications.

The different embodiments of the invention are described by the following examples. However, the present invention is not limited to the described exemplary embodiments; these examples are for illustrative purpose only.

### Example 1

A tin oxide ceramic sputtering target is manufactured based on the following composition:

| | | |
|---|---|---|
| SnO₂ | 96 | wt % |
| Sb₂O₃ | 2 | wt % |
| CuO | 2 | wt % |

The starting ingredients, all in powder form, were mixed and milled in an attritor with water with some amount of dispersing agent (amino alcohol and ammonia polyacrylate). The obtained slip has an average particle size of 0.37 μm and a specific surface area of 6.5 m²/g. An organic binder (a polyacrylic emulsion) is added, and, after slip homogenization, the flat target is shaped by slip casting into a plaster mold. After drying at 90° C., the cast body is fired in an electrical furnace using a zirconia refractory setter. Firing is conducted using a heating rate of 25° C./hr from room temperature to 650° C., then a heating rate of 50° C./hr from 950 to 1050° C. and then of 25° C./hr from 1050 to 1200° C. with a soak of 2.5 hrs at the final temperature using an oxygen gas flow of 1 l/min/kg of product. After 2.5-hr soaking under oxygen flow conditions, the oxygen flow is switched to nitrogen with a flow of 1 l/min/kg of product, and the soak is continued for 2.5 more hrs, then cooling is conducted at a rate of 80° C./hr for 3 hrs in air, after that cooling is continued itself when the power in the furnace is shut off. The obtained ceramic flat body has a density of 99% of the theoretical density TD.

The sintered ceramics have a uniform microcrystalline structure with cassiterite as the major crystalline phase, and other crystalline phases (secondary phases) are not detected by XRD. The grain size of the ceramics is for about 85% in the range of 5-25 μm with a majority (about 70%) of the grains having a size of 7-15 μm. The tile is ground using a diamond wheel tooling to the dimensions of 200×100×8 mm. The electrical resistivity of the ceramics is 2 Ohm·cm measured at room temperature, and the thermal conductivity is 14 W/m-K, measured at 300° C. Both electrical and thermal properties are well suitable for DC magnetron sputtering. The obtained thin films have electrical resistivity and transmittance acceptable for optoelectronic applications.

### Example 2

A tin oxide ceramic sputtering target is manufactured based on the same composition as in Example 1. All required CuO and a part of SnO₂ powders taken in the ratio of 5 wt %-95 wt % are mixed and milled in an attritor with water and a dispersing agent to an average particle size of 0.35 μm and specific surface area of 6.7 m²/g; then the prepared (intermediate) slurry is dried, the dried cake is disintegrated and the powder is fired in electrical furnace using 100° C./hr heating rate with 1 hr soak at the temperature of 900° C. The obtained compound is disintegrated, and it is used for the final slip preparation with the other ingredients (e.g. SnO₂ and Sb₂O₃) using water and the dispersant agent in attritor. An average particle size of the slip is 0.38 μm and specific surface area of the slip is 6.5 m²/g; the slip is drained, a temporary binder is added, and a tile is made by slip casting into plaster mold. Drying and firing are conducted using the same conditions as Example 1, except for the gas flow parameters. Oxygen and nitrogen flows are 1.5 l/min/kg of product. The obtained ceramic flat body has a density of 98.5% of TD. The sintered ceramics has uniform microcrystalline structure with cassiterite as the major crystalline phase, without the presence of other phases. The grain size of the ceramics is for about 90% in the range of 5-25 μm and the majority of the grains (75%) have sizes of 7-15 μm. The tile is ground using diamond wheel tooling to the dimensions of 200×100×8 mm. The electrical resistivity of the ceramics is 3 Ohm·cm measured at room temperature, and the thermal conductivity is 13 W/m-K measured at 300° C. Both electrical and thermal properties are well suitable for DC magnetron sputtering. The obtained thin films have electrical resistivity and transmittance acceptable for optoelectronic applications.

### Example 3

A tin oxide ceramic sputtering target is manufactured based on the following composition:

| | | |
|---|---|---|
| SnO₂ | 96 | wt % |
| Sb₂O₃ | 2 | wt % |
| CuO | 1.5 | wt % |
| CoO | 0.5 | wt % |

The starting ingredients are mixed and milled in an attritor with water and some amount of the dispersing agent. The slip has an average particle size of 0.39 μm and a specific surface area of 6.2 m²/g. The slip is used for press-powder preparation using some amounts of binding (a combination of polyacrylic emulsion and polyethylene glycol) and lubricating components (a combination of oil and solvent, e.g. kerosene). The flat tile is made by uniaxial pressing using a specific pressure of 80 MPa. Firing of the tile is conducted under the same conditions as Example 1, except for the firing temperature and soak time. Firing temperature is 1220° C., with a soak time of 3 hr in oxygen and 3 hrs in nitrogen. Cooling in nitrogen conditions is conducted during 2 hrs, and then cooling is continued in air. The obtained ceramic flat body has a density as 98.5% of TD. The sintered ceramics has uniform microcrystalline structure with cassiterite as the major crystalline phase. The grain size of the ceramics is for about 88% in the range of 5-25 μm when the majority of the grains (70%) have the sizes of 7-15 μm. The tile is ground using diamond wheel tooling to the dimensions of 200×100×10 mm. The electrical resistivity of the ceramics is 4.5 Ohm·cm measured at room temperature, and the thermal conductivity is 11 W/m-K measured at 300° C. Both electrical and thermal properties are well suitable for DC magnetron sputtering. The obtained thin films have electrical resistivity and transmittance acceptable for optoelectronic applications.

### Example 4

A tin oxide ceramic sputtering target is manufactured based on the following composition:

| | | |
|---|---|---|
| SnO₂ | 95.5 | wt % |
| Sb₂O₃ | 2 | wt % |
| CuO | 1.5 | wt % |
| ZnO | 0.6 | wt % |
| Nb₂O₅ | 0.4 | wt % |

The starting ingredients are mixed and milled in a ball mill with water and some amount of the dispersing agent. The slip has an average particle size of 0.36 μm and a specific surface area of 7.0 m²/g. The slip is used for press-powder preparation using some amounts of binding and lubricating components. A hollow cylindrical body and flat bar are made by cold isostatic pressing using a specific pressure of 500 MPa. Firing of the ceramic bodies is conducted using the same conditions as Example 3, except for the firing temperature, being 1200° C., with soak time of 3 hr in oxygen and 3 hrs in nitrogen (the same as in Example 3). The obtained ceramic bodies have density as 97.5% of TD. The sintered ceramics has uniform microcrystalline structure with cassiterite as the major crystalline phase, without the presence of secondary phases, as can be seen on an XRD analysis. The grain size of the ceramics is mostly (78%) in the range of 5-25 μm when the majority of the grains (66%) have the sizes of 7-15 μm. The cylinder is ground using diamond wheel tooling to the dimensions of 147 mm OD (outer diameter)×134 mm ID (inner diameter)×150 mm length and the tile is ground also using diamond wheel tooling to the dimensions of 200×150×10 mm. The electrical resistivity of the ceramics (samples are cut from the tile for convenience) is 7 Ohm·cm measured at room temperature, and the thermal conductivity is 12 W/m-K measured at 300° C. Both electrical and thermal properties are well suitable for DC magnetron sputtering. The obtained thin films have electrical resistivity and transmittance acceptable for optoelectronic applications.

### Example 5

A tin oxide ceramic sputtering target is manufactured based on the same composition and processing as Example 2, only using the ratio of CuO and SnO2 powders as 4 wt.-%-96 wt.-%. An average particle size and specific surface area of the prepared (intermediate) slurry are 0.32 μm and 6.8 m2/g, respectively. The powder obtained by the same method as in Example 2 is fired using the same procedure as in Example 2, but this firing is conducted at 800° C. The consequent processing is in accordance with Example 2 excepting the firing soak conditions. The soak in oxygen is conducted during 2 hrs, but the soak in nitrogen (1 l/min/kg of powder) is conducted during 1.75 hrs, then nitrogen is switched to air, and cooling is processed. The obtained ceramic body (tile) has density of 99% of TD. The sintered ceramics has uniform microcrystalline structure with cassiterite as the major crystalline phase without presence of other phases (not detected by XRD analysis). The grain size of the ceramics is for about 88% in the range of 5-25 μm and the majority of the grains (75%) have sizes of 7-15 μm. The electrical resistivity of the ceramic is 0.05 Ohm·cm measured at room temperature, and the thermal conductivity is 15 W/m-K measured at 300° C. Both electrical and thermal properties are well suitable for DC magnetron sputtering. The obtained thin films have electrical resistivity and transmittance acceptable for optoelectronic applications.

### Example 6

A tin oxide ceramic sputtering target is manufactured based on the following composition:

| | | |
|---|---|---|
| SnO₂ | 96 | wt % |
| Sb₂O₃ | 2 | wt % |
| CuO | 1.5 | wt % |
| Bi₂O₃ | 0.5 | wt % |

The starting ingredients are mixed and milled similarly as described in Example 1, only CuO and Bi₂O₃ are mixed and milled first in the described liquid ingredients for 20 min, and then the other solid ingredients are added. The obtained slip has an average particle size of 0.35 μm and a specific surface area of 6.9 m²/g. An organic binder (a polyacrylic emulsion) is added, and, after slip homogenization, the flat target is shaped by slip casting into a plaster mold. Then processing (drying and firing) is conducted as in Example 5. The obtained ceramic bodies have a density of 99.3% of TD. The sintered ceramics have a uniform microcrystalline structure with cassiterite as the major crystalline phase, without the presence of secondary phases, as can be seen on an XRD analysis. The grain size of the ceramics is mostly (80%) in the range of 5-25 μm where the majority of the grains (70%) have the sizes of 7-15 μm. The flat tile is ground using diamond wheel tooling to the dimensions of 200×100×8 mm. The electrical resistivity of the ceramics (samples are cut from the tile for convenience) is 0.035 Ohm·cm measured at room temperature, and the thermal conductivity is 15 W/m-K measured at 300° C. Both electrical and thermal properties are well suitable for DC magnetron sputtering. The obtained thin films have an electrical resistivity and transmittance acceptable for optoelectronic applications.

### Example 7

A tin oxide ceramic sputtering target is manufactured based on the same composition and processing as Example 6, only shaping of the target is conducted by pressure filtration providing the dewatering of the slurry through a polymeric membrane. The obtained ceramic target (a disc with diameter 150 mm and thickness 7 mm after grinding) has a density of 99.2% of TD, electrical resistivity of 0.04 Ohm·cm measured at room temperature and thermal conductivity of 14 W/m-K measured at 300° C. Both electrical and thermal properties are well suitable for DC magnetron sputtering. The obtained thin films have electrical resistivity and transmittance acceptable for optoelectronic applications.

### Comparative Example 1

A tin oxide ceramic sputtering target is manufactured based on the same composition as in Example 1. The starting ingredients are mixed and milled using the same procedure, only the slip has an average particle size of 0.48 μm and a specific surface area of 4.0 m²/g. Shaping and firing processes are also conducted as in Example 1 (firing temperature is 1175° C.). However, firing density is only 88% of TD. The electrical resistivity of the ceramics is 65 Ohm·cm. The thermal conductivity of the ceramics is 6 W/m-K, and that value may be not enough for appropriate temperature transfer during sputtering, with the possibility of the occurrence of cracks in the target.

### Comparative Example 2

A tin oxide ceramic sputtering target is manufactured based on the same composition as in Example 1. The starting ingredients are mixed and milled using the same procedure, achieving a slip average particle size of 0.38 μm and specific surface area of 6.5 m²/g. Shaping and firing processes are also conducted as in Example 1, but the flow of nitrogen is not introduced (the full firing is conducted in slight oxidation conditions). Firing density is 99.5% of TD. However, electrical resistivity of the ceramics is 150-200 Ohm·cm, and that is rather high for DC magnetron sputtering.

### Comparative Example 3

A tin oxide ceramic sputtering target is manufactured based on the same composition as in Example 3. The starting ingredients are mixed and milled using the same procedure, the shaping process and parameters are also the same as in Example 3. Firing processes is conducted at 1300° C., but the gaseous conditions were the same as in Example 3. However, the firing density is only 85% of TD and the obtained product has deformation and small cracks. The ceramics do not have a very uniform microstructure with an unacceptable presence (about 25-35%) of large and elongated grains with sizes of 20 to 40 μm. The electrical resistivity of the ceramics is 1350-1500 Ohm·cm, which is too high and not appropriate for DC magnetron sputtering.

While specific embodiments and/or details of the invention have been shown and described above to illustrate the application of the principles of the invention, it is understood that this invention may be embodied as more fully described in the claims and clauses, or as otherwise known by those skilled in the art (including any and all equivalents), without departing from such principles.

The invention can alternatively be described by the following clauses:

1. A sputtering target comprising a ceramic body, the ceramic body comprising tin oxide and between 0.5 and 15 wt % of at least two other oxides, one of the at least two other oxides being antimony oxide and the other of the at least two other oxides being selected from the group consisting of CuO, CoO, Bi₂O₃, ZnO, Al₂O₃, TiO₂, MnO₂, In₂O₃, Ga₂O₃, GeO₂, SiO₂, P₂O₅, Nb₂O₅, and combinations thereof, or the other of the at least two other oxides being ZnO and Nb₂O₅, wherein said target has a density of at least 90% of the theoretical density (TD) and an electrical resistivity of less than 50 Ohm·cm, and wherein said target has a planar or rotary configuration with a sputtering area of at least 10 cm².

2. The sputtering target according to clause 1, wherein said target has a density of at least 95% of the theoretical density (TD).

3. The sputtering target according to clauses 1 or 2, wherein said target has a sputtering area of at least 20 cm².

4. The sputtering target according to any one of clauses 1 to 3, wherein said target has a planar or rotary configuration with a sputtering area of at least 100 cm².

5. The sputtering target according to any one of clauses 1 to 4, wherein said target has a rotary configuration consisting of a hollow cylinder having a diameter of at least 10 cm.

6. The sputtering target according to any one of clauses 1 to 5, wherein the ceramic body of said target has a thickness of at least 4 mm.

7. The sputtering target according to any one of clauses 1 to 6, wherein the thermal conductivity of said target is in the range of 10 to 20 W/m-K at 300° C.

8. The sputtering target according to any one of clauses 1 to 7, wherein said target has an electrical resistivity of less than 10 Ohm·cm.

9. The sputtering target according to any one of clauses 1 to 8, wherein said target has an electrical resistivity of less than 0.2 Ohm·cm.

10. The sputtering target according to any one of clauses 1 to 9, wherein said target has a uniform microstructure consisting of particles, of which between 60 to 90% having a grain size between 5 and 25 μm, and between 65 to 75% having a grain size between 7 and 15 μm; and said microstructure consisting of less than 10% of a secondary phase.

11. The sputtering target according to any one of clauses 1 to 10, wherein said target comprises, besides tin oxide, between 0.5 and 15 wt % of at least three other oxides, one of which being antimony oxide, the at least two other oxides being selected from the group consisting of:
CuO and CoO,
CuO, ZnO and Al₂O₃,
CuO, ZnO and Nb₂O₅,
CuO and Ga₂O₃, and
CuO and Bi₂O₃.

12. The sputtering target according to clause 1, wherein said ceramic body comprises between 1.5 and 5 wt % of said at least two other oxides.

13. The sputtering target according to clause 12, the ceramic body comprising between 95.5 and 97 wt % of tin oxide, between 1 and 2.5 wt % of antimony oxide, and between 0.5 and 2 wt % of CuO, wherein the sum of tin oxide, antimony oxide and CuO is 100%.

14. The sputtering target according to clause 12, the ceramic body comprising between 95.5 and 97 wt % of tin oxide, between 1 and 2.5 wt % of antimony oxide, between 0.5 and 2 wt % of CuO, and between 0.05 and 1 wt % of CoO, wherein the sum of tin oxide, antimony oxide, CuO and CoO is 100%.

15. The sputtering target according to clause 12, the ceramic body comprising between 95.5 and 97 wt % of tin oxide, between 1 and 2.5 wt % of antimony oxide, between 0.5 and 2 wt % of CuO, between 0.1 and 1 wt % of ZnO, and between 0.001 and 0.003 wt % of Al₂O₃, wherein the sum of tin oxide, antimony oxide, CuO, ZnO and Al₂O₃ is 100%.

16. The sputtering target according to clause 12, the ceramic body comprising between 95.5 and 97 wt % of tin oxide, between 1 and 2.5 wt % of antimony oxide, between 0.5 and 2 wt % of CuO, between 0.1 and 1 wt % of ZnO, and between 0.05 and 0.5 wt % of Nb₂O₅, wherein the sum of tin oxide, antimony oxide, CuO, ZnO and Nb₂O₅ is 100%.

17. The sputtering target according to clause 12, the ceramic body comprising between 95.5 and 97 wt % of tin oxide, between 1 and 2.5 wt % of antimony oxide, between 0.5 and 2 wt % of CuO, and between 0.05 and 1 wt % of Ga₂O₃, wherein the sum of tin oxide, antimony oxide, CuO and Ga₂O₃ is 100%.

18. The sputtering target according to clause 12, the ceramic body comprising between 95.5 and 97 wt % of tin oxide, between 1 and 2.5 wt % of antimony oxide, between 0.5 and 2 wt % of CuO, and between 0.05 and 1 wt % of Bi₂O₃, wherein the sum of tin oxide, antimony oxide, CuO and Bi₂O₃ is 100%.

19. A process for manufacturing a sputtering target comprising a ceramic body, the ceramic body comprising tin oxide and between 0.5 and 15 wt % of at least two other oxides, one of the at least two other oxides being antimony oxide and the other of the at least two other oxides being selected from the group consisting of CuO, CoO, Bi₂O₃, ZnO, Al₂O₃, MnO₂, In₂O₃, Ga₂O₃, GeO₂, SiO₂, P₂O₅, Nb₂O₅, and combinations thereof, or the other of the at least two other oxides being ZnO and Nb₂O₅, wherein said target has a density of at least 90% of the theoretical density (TD) and an electrical resistivity of less than 50 Ohm·cm, and wherein said target has a planar or rotary configuration with a sputtering area of at least 10 cm², the process comprising:
providing a slurry comprising tin oxide and said at least two other oxides,
shaping a green body from said slurry,
heating said green body, and firing at a temperature between 1050 and 1250° C., thereby obtaining a pre-shaped target, and
grinding said pre-shaped target to its final dimensions.

20. The process for manufacturing a sputtering target according to clause 19, said target having a given composition, wherein the step of providing slurry comprises:
providing quantities of tin oxide and said at least two other oxides, the ratio of a said quantities corresponding to the composition of the ceramic sputtering target,
providing an intermediate slurry comprising at least part of said tin oxide and at least part of said at least two other oxides,
drying said intermediate slurry to obtain a dry cake,
crushing said cake to obtain an intermediate powder,
firing said intermediate powder at a temperature between 700 and 950° C.,
de-agglomerating said fired intermediate powder,
mixing said de-agglomerated powder with the remainder of said quantities of tin oxide and said at least two other oxides to obtain a mixture,
forming the slurry comprising tin oxide and said at least two other oxides.

21. The process for manufacturing a ceramic sputtering target according to clause 20, said target comprising between 95.5 and 97 wt % of tin oxide, between 1 and 2.5 wt % of antimony oxide, and between 0.5 and 2 wt % of CuO, wherein said intermediate slurry consists of part of said quantity of said tin oxide, and all of the quantity of CuO.

22. The process for manufacturing a sputtering target according to any one of clauses 19 to 21, wherein the tin oxide and the at least two other oxides in said slurry have an average particle size of less than 0.5 μm.

23. The process for manufacturing a sputtering target according to any one of clauses 19 to 21, wherein the tin oxide and the at least two other oxides in said slurry have a specific surface area of at least 5.5 m²/g.

24. The process for manufacturing a sputtering target according to any one of clauses 19 to 23, wherein said firing said green body at a temperature between 1050 and 1250° C. is performed in a furnace during a soaking period of 2 to 7 hrs.

25. The process for manufacturing a sputtering target according to clause 24, wherein in said furnace, during the heating up to the firing temperature, and during a first part of said soaking period, there is a flow of oxygen, and during a second part of said soaking period, there is a flow of a reducing gas.

26. The process for manufacturing a sputtering target according to clause 25, wherein said flow of both said oxygen and said reducing gas is between 0.25 and 2.5 l/min per kg of said green body.

27. The process for manufacturing a sputtering target according to clause 22, wherein the tin oxide and the at least two other oxides in said slurry have an average particle size of less than 0.4 μm.

28. The process for manufacturing a sputtering target according to clause 25, wherein the reducing gas is nitrogen.

1-27. (canceled)

28. A sputtering target comprising a ceramic body having tin oxide as a major constituent and between 0.5 and 15 wt % of at least two other oxides, one of the at least two other oxides being antimony oxide and the other of the at least two other oxides being selected from the group consisting of CuO, CoO, Bi₂O₃, ZnO, Al₂O₃, TiO₂, MnO₂, In₂O₃, Ga₂O₃, GeO₂, SiO₂, P₂O₅, and a combination of ZnO and Nb₂O₅, said target having a density of at least 90% of the theoretical density (TD) and an electrical resistivity of less than 50 Ohm·cm, wherein said target has a planar or rotary configuration with a sputtering area of at least 10 cm².

29. The sputtering target of claim 28, wherein said target has a density of at least 95% of the theoretical density (TD).

30. The sputtering target of claim 28, wherein said target has a sputtering area of at least 20 cm².

31. The sputtering target of claim 28, wherein said target has a planar or rotary configuration with a sputtering area of at least 100 cm².

32. The sputtering target of claim 28, wherein said target has a rotary configuration consisting of a hollow cylinder having a diameter of at least 10 cm.

33. The sputtering target of claim 28, wherein the ceramic body of said target has a thickness of at least 4 mm.

34. The sputtering target of claim 28, wherein the thermal conductivity of said target is in the range of 10 to 20 W/m-K at 300° C.

35. The sputtering target of claim 28, wherein said target has an electrical resistivity of less than 10 Ohm·cm.

36. The sputtering target of claim 28, wherein said target has an electrical resistivity of less than 0.2 Ohm·cm.

37. The sputtering target of claim 28, wherein said target has a uniform microstructure comprising particles, of which between 60 to 90% have a grain size between 5 and 25 μm, and between 65 to 75% have a grain size between 7 and 15 μm; and said microstructure comprising less than 10% of a secondary phase.

38. The sputtering target of claim 28, wherein said target comprises tin oxide and between 0.5 and 15 wt % of at least three other oxides, one of the at least three other oxides being antimony oxide, and the at least two other oxides being selected from the group consisting of:
CuO and CoO,
CuO, ZnO and Al₂O₃,
CuO, ZnO and Nb₂O₅,
CuO and Ga₂O₃, and
CuO and Bi₂O₃.

39. The sputtering target of claim 28, wherein said target comprises tin oxide, antimony oxide, and between 1.5 and 5 wt % of an oxide selected from the group consisting of CuO, CoO, Bi₂O₃, ZnO, Al₂O₃, TiO₂, MnO₂, In₂O₃, Ga₂O₃, GeO₂, SiO₂, P₂O₅, and a combination of ZnO and Nb₂O₅.

40. The sputtering target of claim 39, comprising between 95.5 and 97 wt % of tin oxide, between 1 and 2.5 wt % of antimony oxide, and between 0.5 and 2 wt % of CuO, the sum of tin oxide, antimony oxide and CuO being 100%.

41. The sputtering target of claim 40, further comprising between 0.05 and 1 wt % of CoO, the sum of tin oxide, antimony oxide, CuO and CoO being 100%.

42. The sputtering target of claim 40, further comprising between 0.1 and 1 wt % of ZnO and between 0.001 and 0.003 wt % of Al₂O₃, the sum of tin oxide, antimony oxide, CuO, ZnO and Al₂O₃ being 100%.

43. The sputtering target of claim 40, further comprising between 0.1 and 1 wt % of ZnO and between 0.05 and 0.5 wt % of Nb₂O₅, the sum of tin oxide, antimony oxide, CuO, ZnO and Nb₂O₅ being 100%.

44. The sputtering target of claim 40, further comprising between 0.05 and 1 wt % of Ga₂O₃, the sum of tin oxide, antimony oxide, CuO and Ga₂O₃ being 100%.

45. The sputtering target of claim 40, further comprising between 0.05 and 1 wt % of Bi₂O₃, the sum of tin oxide, antimony oxide, CuO and Bi₂O₃ being 100%.

46. A process for manufacturing the sputtering target of claim 28, comprising:
providing a slurry comprising tin oxide and said at least two other oxides,
shaping a green body from said slurry,
heating said green body, and firing at a temperature between 1050 and 1250° C., thereby obtaining a pre-shaped target, and
grinding said pre-shaped target to its final dimensions.

47. The process of claim 46, said target having a given composition, wherein providing a slurry comprises:
providing quantities of tin oxide and said at least two other oxides, the ratio of said quantities corresponding to the given composition of the ceramic sputtering target,
providing an intermediate slurry comprising at least part of said tin oxide and at least part of said at least two other oxides,
drying said intermediate slurry to obtain a dry cake,
crushing said cake to obtain an intermediate powder,
firing said intermediate powder at a temperature between 700 and 950° C.,
de-agglomerating said fired intermediate powder, and
mixing said de-agglomerated powder with the remainder of said quantities of tin oxide and said at least two other oxides, and using said mixture to form a slurry.

48. The process of claim 47, wherein said target comprises between 95.5 and 97 wt % of tin oxide, between 1 and 2.5 wt % of antimony oxide, and between 0.5 and 2 wt % of CuO, the sum of tin oxide, antimony oxide and CuO being 100%, and wherein said intermediate slurry comprises part of said quantity of said tin oxide, and all of the quantity of CuO.

49. The process of claim 46, wherein the tin oxide and the at least two other oxides in said slurry have an average particle size of less than 0.5 μm.

50. The process of claim 46, wherein the tin oxide and the at least two other oxides in said slurry have a specific surface area of at least 5.5 m²/g.

51. The process of claim 46, wherein said firing of said green body at a temperature between 1050 and 1250° C. is performed in a furnace during a soaking period of 2 to 7 hrs.

52. The process of claim 51, wherein in said furnace, during heating up to the firing temperature, and during a first part of said soaking period, there is a flow of oxygen, and during a second part of said soaking period, there is a flow of reducing gas comprising nitrogen.

53. The process of claim 52, wherein the flow of oxygen and reducing gas is between 0.25 and 2.5 l/min per kg of said green body.
